(19) United States
(12) Patent Application Publication
(10) Pub. No.: US 2025/0254914 A1
(43) Pub. Date: Aug. 7, 2025

(54) SEMICONDUCTOR DEVICE AND MANUFACTURING METHOD THEREOF

(71) Applicant: TAIWAN SEMICONDUCTOR MANUFACTURING COMPANY, LTD., Hsinchu (TW)

(72) Inventors: Szu-Chien WU, Hsinchu County (TW); Chun-Yuan CHEN, Hsinchu (TW); Huan-Chieh SU, Changhua County (TW); Chih-Hao WANG, Hsinchu County (TW)

(73) Assignee: TAIWAN SEMICONDUCTOR MANUFACTURING COMPANY, LTD., Hsinchu (TW)

(21) Appl. No.: 18/431,140

(22) Filed: Feb. 2, 2024

(51) Int. Cl. H01L 29/417; H01L 21/285; H01L 29/06; H01L 29/40; H01L 29/423; H01L 29/45; H01L 29/66; H01L 29/775

(52) U.S. Cl. CPC H10D 30/6729; H01L 21/28518; H10D 30/014; H10D 30/43; H10D 30/6735; H10D 62/121; H10D 64/01; H10D 64/62

(57) ABSTRACT

A semiconductor device comprises semiconductor layers extending over a substrate, a gate structure, gate spacers, epitaxial source/drain structures, a conductive contact and a lower dielectric plug. The gate structure wraps around the semiconductor layers. The gate spacers are on opposite sidewalls of the gate structure. The epitaxial source/drain structures are on opposite sides of the metal gate structure. The conductive contact is over a first one of the epitaxial source/drain structures. The lower dielectric plug is over a second one of epitaxial source/drain structures, wherein from a cross-sectional view, the gate spacers are between the lower dielectric plug and the conductive contact, wherein from a plan view, the lower dielectric plug and the conductive contact have a same pattern.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 2A, 3A, 4A, 8, 9, 10, 11, 12, 13A, 14 and 15A are perspective views of some embodiments of the semiconductor device at intermediate stages during fabrication.

FIGS. 1B, 2B, 3B and 4B are cross-sectional views of some embodiments of the semiconductor device during fabrication along a first cut (e.g., cut line B-B in corresponding FIGS. 1A, 2A, 3A and 4A), which is along a lengthwise direction of the channel (semiconductor layer).

FIGS. 5A, 6A and 7A are cross-sectional views of some embodiments of the semiconductor device during fabrication along a second cut (e.g., cut A-A, See FIG. 1A), which is along a lengthwise direction of the dummy gate structure.

FIGS. 5B, 6B and 7B are cross-sectional views of some embodiments of the semiconductor device during fabrication along the first cut (e.g., cut line B-B, See FIG. 1A).

FIGS. 13B, 13C and 13D are cross-sectional views of some embodiments of the semiconductor device during fabrication along Y-direction in FIG. 13A.

FIG. 15B is a top view of FIG. 15A in accordance with some embodiments.

FIG. 15C is a cross-sectional view of some embodiments of the semiconductor device during fabrication along Y-direction in FIG. 15A.

FIG. 15D is a cross-sectional view of some other embodiments of the semiconductor device during fabrication along Y-direction in FIG. 15A.

FIG. 15E is a cross-sectional view of some other embodiments of the semiconductor device during fabrication along X-direction in FIG. 15A.

FIG. 15F is a cross-sectional view of some embodiments of the semiconductor device during fabrication along X-direction in FIG. 15A.

FIG. 15G is a cross-sectional view of some embodiments of the semiconductor device during fabrication along Y-direction in FIG. 15A.

FIG. 16A is a top view of some other embodiments of the semiconductor device during fabrication.

FIG. 16B is a cross-sectional view of some embodiments of the semiconductor device during fabrication along X1-X1 line in FIG. 16A.

FIG. 17A is a top view of some other embodiments of the semiconductor device during fabrication.

FIG. 17B is a cross-sectional view of some embodiments of the semiconductor device during fabrication along Y1-Y1 line in FIG. 17A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “etch selectivity” refers to the ratio of the etch rates of two different materials under the same etching conditions. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9). As used herein, the term “low-k” refers to a low dielectric constant. In the field of semiconductor device structures and manufacturing processes, low-k refers to a dielectric constant that is less than the dielectric constant of SiO₂ (e.g., less than 3.9). As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Transistors may include gates located between source/drain (S/D) regions, and source/drain contacts are formed on the S/D regions and spaced apart from the gates. Source/drain contact formation process is performed to form S/D contacts. The S/D contact formation process may also be referred to as an MD formation process. The MD formation process may include depositing MD lines and cutting the MD lines to obtain a desired position of the MDs. However, some of the MDs are not configured to provide function of wiring and can be referred to as dummy MDs. Parasitic capacitance may be present between the gates and the dummy MDs, which decreases the device performance of the transistors.

Embodiments of the present disclosure provide a method of replacing the dummy MDs with a dielectric material. Therefore, parasitic capacitance present between the gates and the dummy MDs can be prevented.

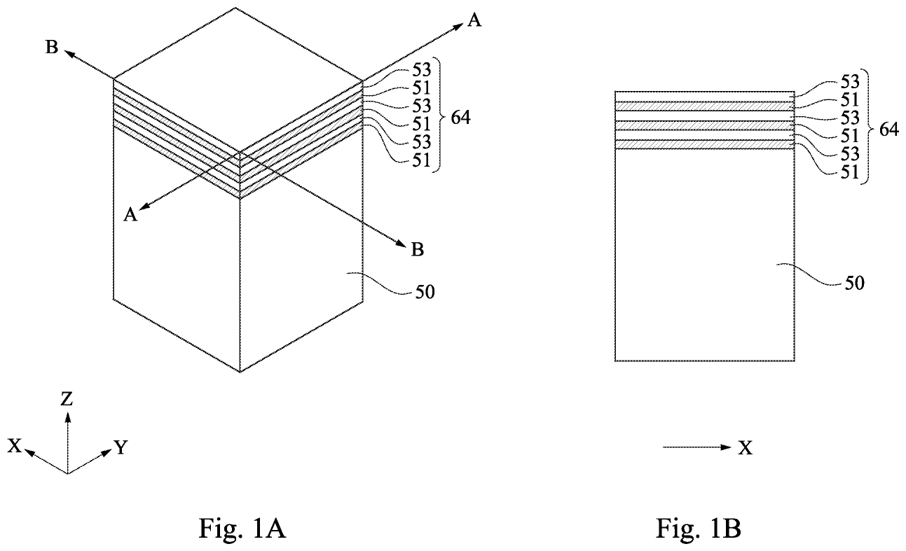

FIGS. 1A-17B illustrate a method for manufacturing a semiconductor device (or an integrated circuit structure) at various stages in accordance with some embodiments of the present disclosure. In some embodiments, the semiconductor device shown in FIGS. 1A-17B may be intermediate devices fabricated during processing of an integrated circuit (IC), or a portion thereof, that may include static random access memory (SRAM), logic circuits, passive components, such as resistors, capacitors, and inductors, and/or active components, such as p-type field effect transistors (PFETs), n-type FETs (NFETs), multi-gate FETs, metal-oxide semiconductor field effect transistors (MOSFETs), complementary metal-oxide semiconductor (CMOS) transistors, bipolar transistors, high voltage transistors, high frequency transistors, other memory cells, and combinations thereof.

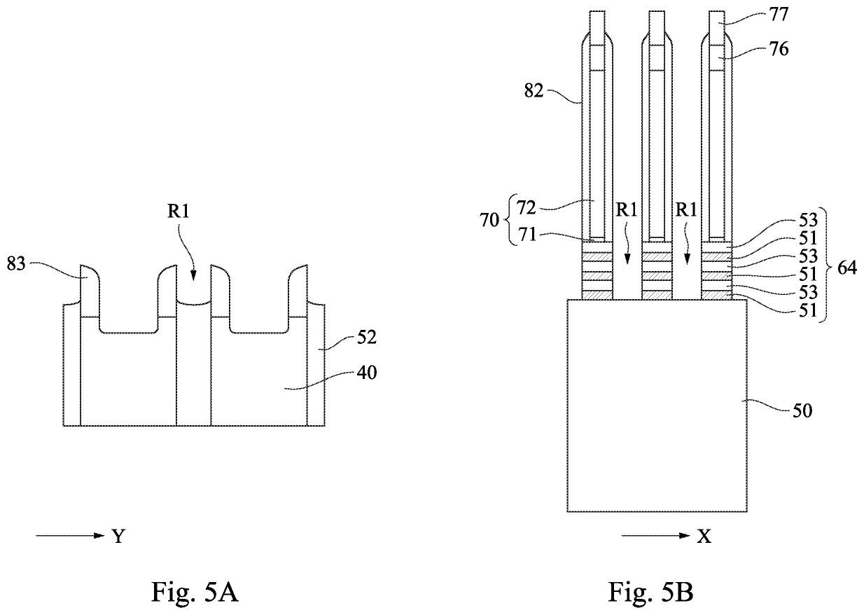

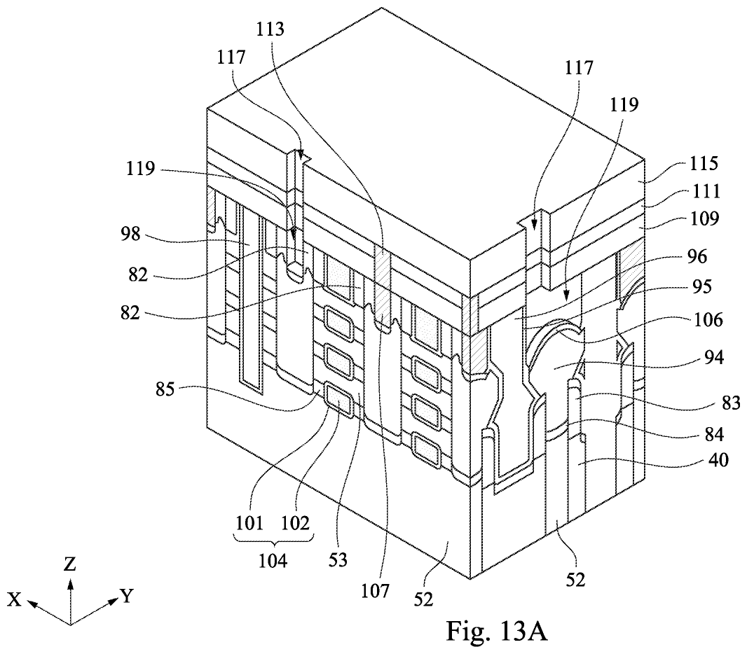

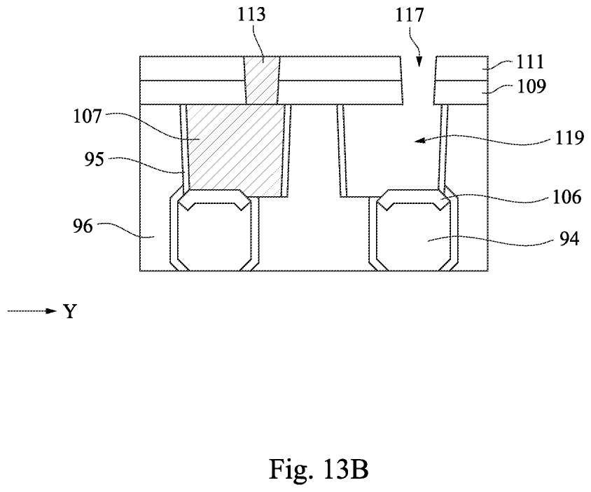

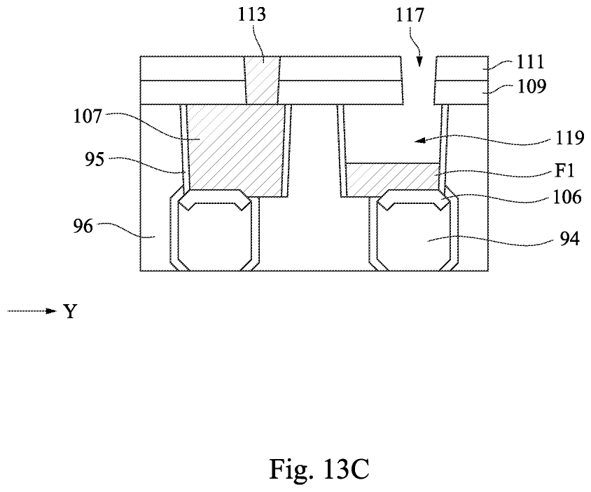

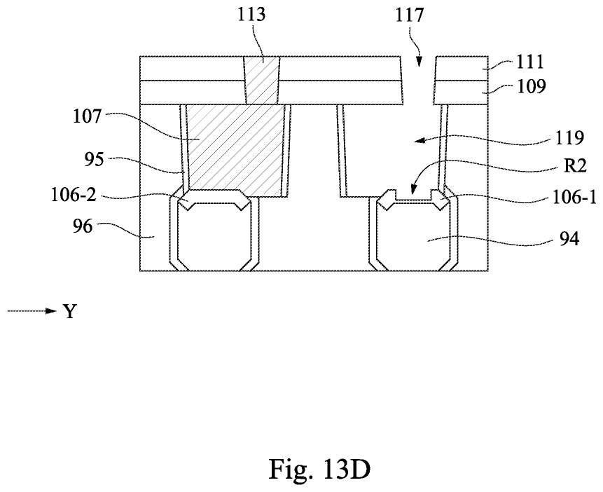

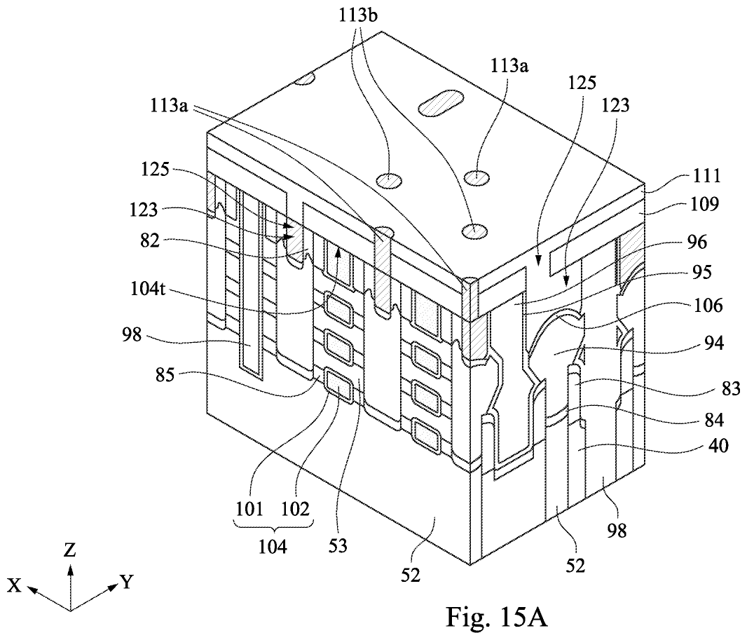

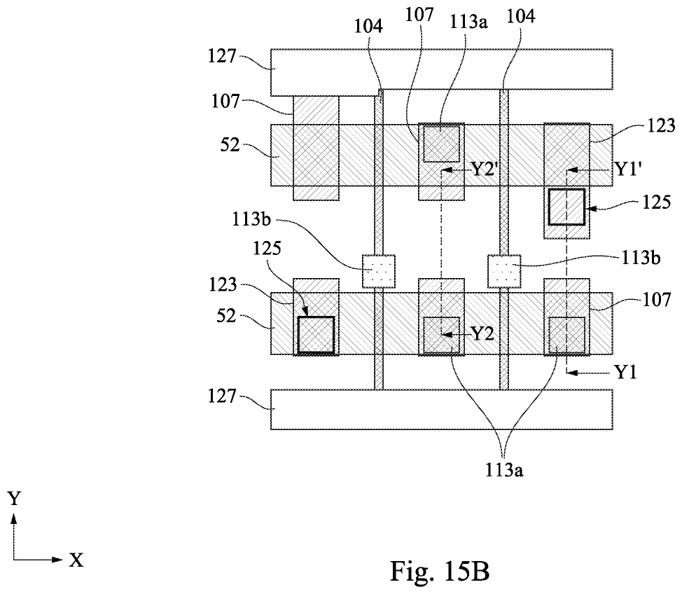

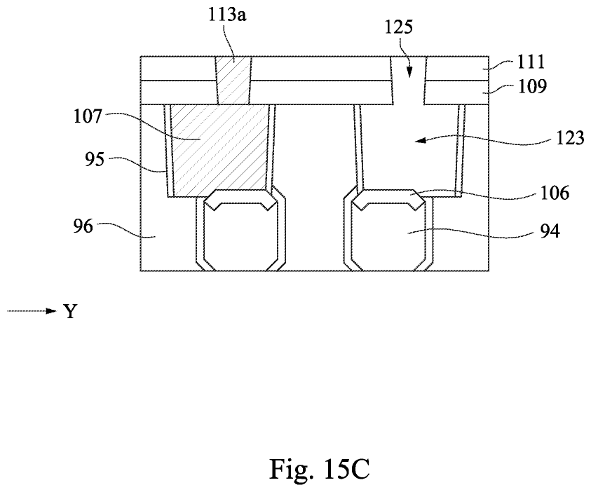

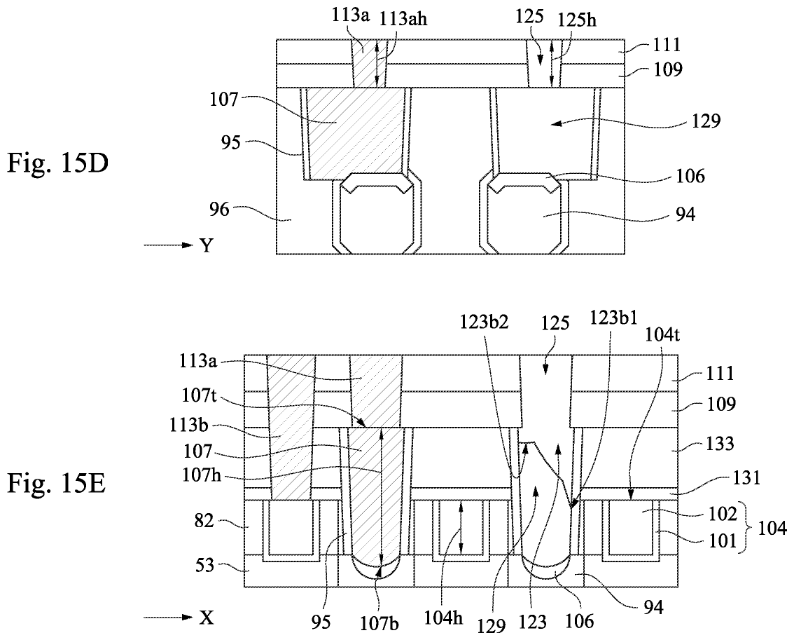

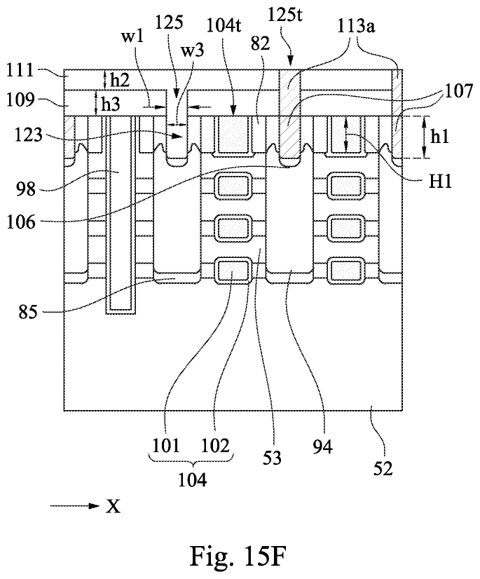

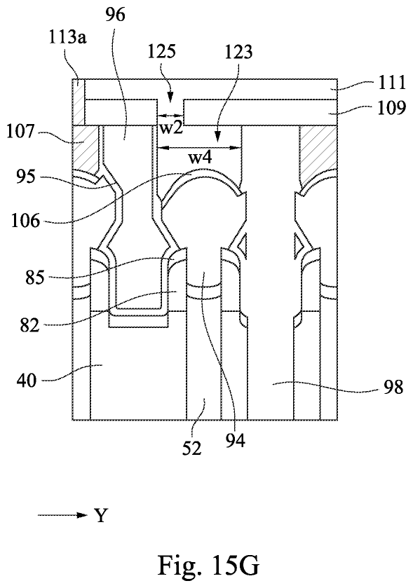

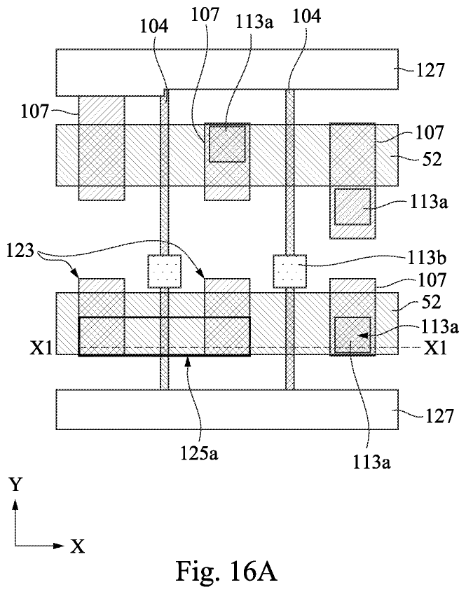

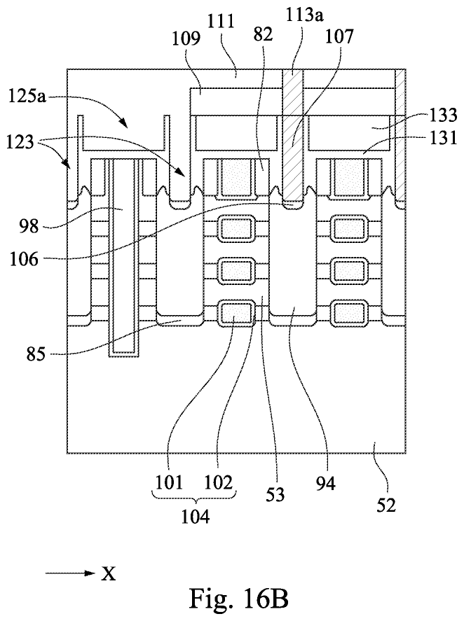

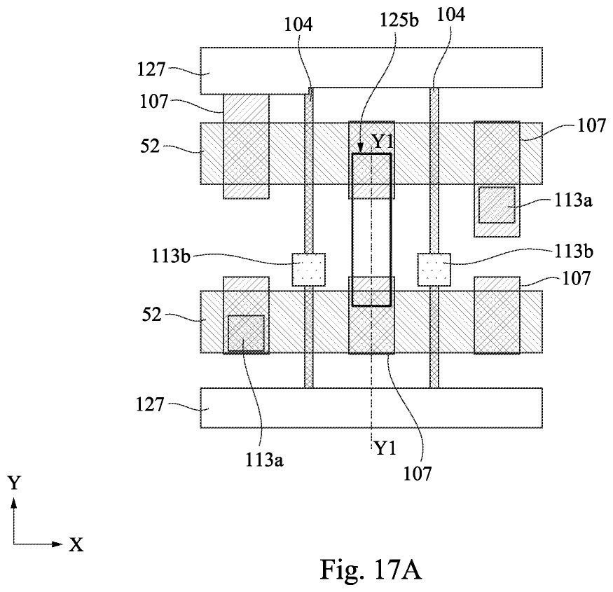

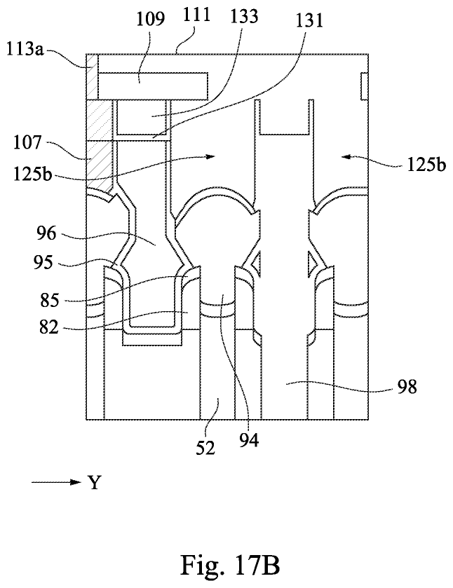

FIGS. 1A, 2A, 3A, 4A, 8, 9, 10, 11, 12, 13A, 14 and 15A are perspective views of some embodiments of the semiconductor device at intermediate stages during fabrication. FIGS. 1B, 2B, 3B and 4B are cross-sectional views of some embodiments of the semiconductor device during fabrication along a first cut (e.g., cut line B-B in corresponding FIGS. 1A, 2A, 3A and 4A), which is along a lengthwise direction of the channel (semiconductor layer). FIGS. 5A, 6A and 7A are cross-sectional views of some embodiments of the semiconductor device during fabrication along a second cut (e.g., cut A-A, See FIG. 1A), which is along a lengthwise direction of the dummy gate structure. FIGS. 5B, 6B and 7B are cross-sectional views of some embodiments of the semiconductor device during fabrication along the first cut (e.g., cut line B-B, See FIG. 1A). FIG. 13B is a cross-sectional view of some embodiments of the semiconductor device during fabrication along Y-direction in FIG. 13A. FIG. 15B is a top view of FIG. 15A. FIG. 15C is a cross-sectional view of some embodiments of the semiconductor device during fabrication along Y-direction in FIG. 15A. FIG. 15D is a cross-sectional view of some other embodiments of the semiconductor device during fabrication along Y-direction in FIG. 15A. FIG. 15E is a cross-sectional view of some other embodiments of the semiconductor device during fabrication along X-direction in FIG. 15A. FIG. 15F is a cross-sectional view of some embodiments of the semiconductor device during fabrication along X-direction in FIG. 15A. FIG. 15G is a cross-sectional view of some embodiments of the semiconductor device during fabrication along Y-direction in FIG. 15A. FIG. 16A is a top view of some other embodiments of the semiconductor device during fabrication. FIG. 16B is a cross-sectional view of some embodiments of the semiconductor device during fabrication along X1-X1 line in FIG. 16A. FIG. 17A is a top view of some other embodiments of the semiconductor device during fabrication. FIG. 17B is a cross-sectional view of some embodiments of the semiconductor device during fabrication along Y1-Y1 line in FIG. 17A.

Reference is made to FIGS. 1A and 1B, in which FIG. 1B is a cross-sectional view along line B-B of FIG. 1A. Shown there is a substrate 50. The substrate 50 may be a semiconductor substrate, such as a bulk semiconductor, a semiconductor-on-insulator (SOI) substrate, or the like. The substrate 50 may be a wafer, such as a silicon wafer. Generally, an SOI substrate comprises a layer of a semiconductor material formed on an insulator layer. The insulator layer may be, for example, a buried oxide (BOX) layer, a silicon oxide layer, or the like. The insulator layer is provided on a substrate, a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed over the substrate 50. The multi-layer stack 64 includes alternating layers of first semiconductor layers 51 and second semiconductor layers 53. For purposes of illustration and as discussed in greater detail below, the first semiconductor layers 51 will be removed and the second semiconductor layers 53 will be patterned to form channel regions of nano-FETs.

The multi-layer stack 64 is illustrated as including three layers of each of the first semiconductor layers 51 and the second semiconductor layers 53 for illustrative purposes. In some embodiments, the multi-layer stack 64 may include suitable number of the first semiconductor layers 51 and the second semiconductor layers 53. For example, there may be two to six pairs of the first semiconductor layer 51 and the second semiconductor layer 53.

The first semiconductor layers 51 and the second semiconductor layers 53 may include different materials and/or components, such that the first semiconductor layers 51 and the second semiconductor layers 53 have different etching rates. In some embodiments, the first semiconductor layers 51 are made from SiGe. The second semiconductor layers 53 may be pure silicon layers that are free of germanium. The second semiconductor layers 53 may also be substantially pure silicon layers, for example, with a germanium percentage lower than about 1 percent. In some embodiments, the first semiconductor layers 51 have a higher germanium atomic percentage concentration than the second semiconductor layers 53. The first semiconductor layers 51 and the second semiconductor layers 53 may be formed by chemical vapor deposition (CVD), molecular beam epitaxy (MBE), or other suitable process(es). In some embodiments, the first semiconductor layers 51 and the second semiconductor layers 53 are formed by an epitaxy growth process, and thus the first semiconductor layers 51 and the second semiconductor layers 53 can also be referred to as epitaxial layers in this content.

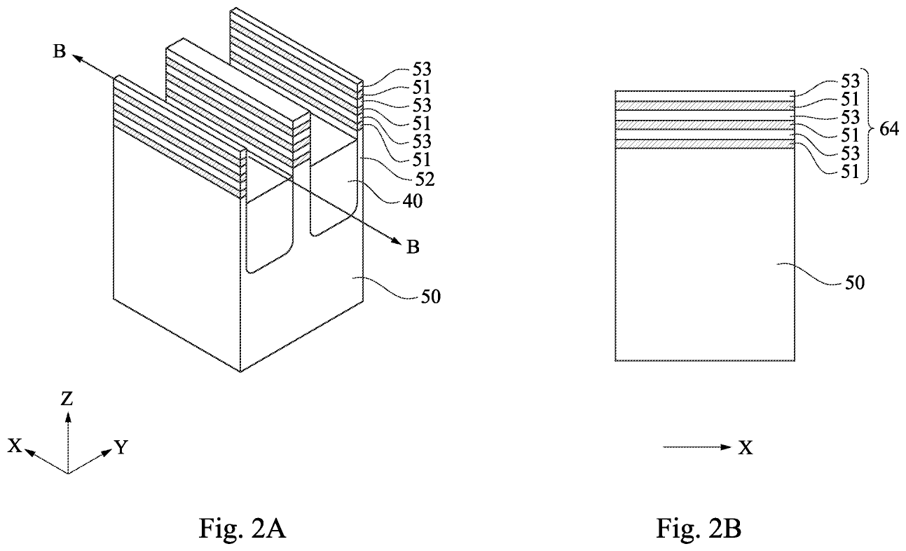

Reference is made to FIGS. 2A and 2B, in which FIG. 2B is a cross-sectional view along line B-B of FIG. 2A. The multi-layer stack 64 and the substrate 50 are patterned. Semiconductor strips 52 are formed protruding over the substrate 50. In some embodiments, the patterning may be formed by etching trenches in the multi-layer stack 64 and the substrate 50. The etching may be any acceptable etch process, such as a reactive ion etch (RIE), neutral beam etch (NBE), the like, or a combination thereof. The etching may be anisotropic. In some embodiments, the patterned semiconductor layers 51, 53, and the underlying semiconductor strip 52 can be collectively referred to as a fin structure.

The substrate 50 and the multi-layer stack 64 may be patterned by any suitable method. For example, the substrate 50 and the multi-layer stack 64 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the substrate 50 and the multi-layer stack 64.

Isolation structures 40 may be formed over the substrate 50 and laterally surrounding the semiconductor strips 52. The isolation structures 40 can be referred to as shallow trench isolation (STI) structures. The isolation structures 40 can be formed by, for example depositing a dielectric material blanket over the substrate 50 and overfilling the spaces between the semiconductor strips 52, performing a planarization process such as chemical mechanical polish (CMP) to remove excess dielectric material until the top surfaces of the semiconductor layers 53 are exposed. Afterward, the dielectric material is recessed, for example, through an etching operation, wherein diluted HF, SiCoNi (including HF and NH₃), or the like, may be used as the etchant.

In some embodiments, the isolation structures 40 are made of silicon oxide, silicon nitride, silicon oxynitride, fluoride-doped silicate glass (FSG), or other low-K dielectric materials. In some embodiments, the isolation structures 40 may be formed using a high-density-plasma (HDP) chemical vapor deposition (CVD) process, using silane (SiH₄) and oxygen (O₂) as reacting precursors. In some other embodiments, the isolation structures 40 may be formed using a sub-atmospheric CVD (SACVD) process or high aspect-ratio process (HARP), wherein process gases may comprise tetraethylorthosilicate (TEOS) and ozone (O₃). In yet other embodiments, the isolation structures 40 may be formed using a spin-on-dielectric (SOD) process, such as hydrogen silsesquioxane (HSQ) or methyl silsesquioxane (MSQ). Other processes and materials may be used. In some embodiments, the isolation structures 40 can have a multi-layer structure, for example, a thermal oxide liner layer with silicon nitride formed over the liner. Thereafter, a thermal annealing may be optionally performed to the isolation structures 40.

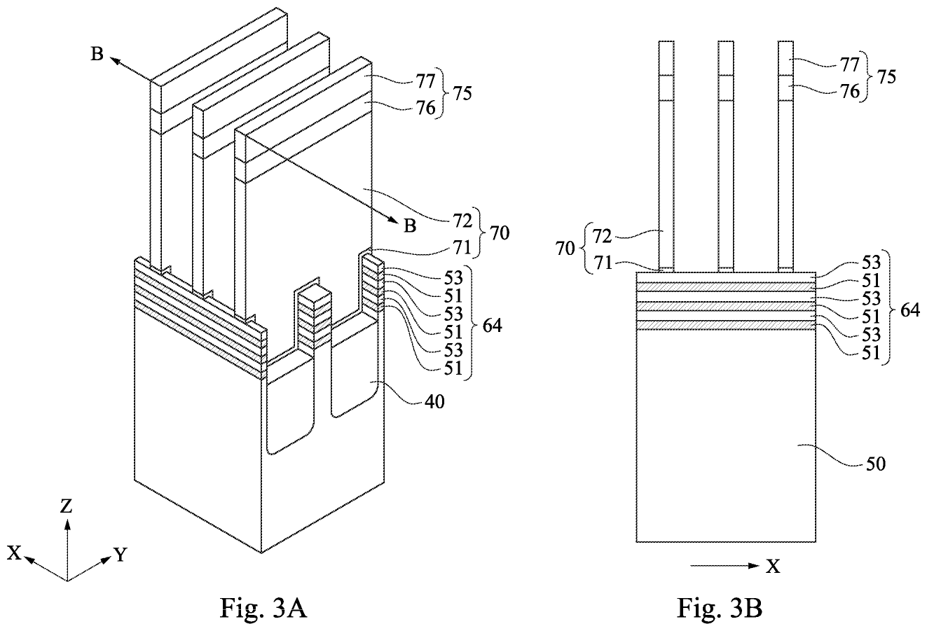

Reference is made to FIGS. 3A and 3B, in which FIG. 3B is a cross-sectional view along line B-B of FIG. 3A. Dummy gate structures 70 are formed over the substrate 50 and crossing the stack 64 of the first semiconductor layers 51 and the second semiconductor layers 53. In some embodiments, patterned masks 75 may be formed over the dummy gate structures 70.

In some embodiments, each of the dummy gate structures 70 includes a dummy gate dielectric 71 and a dummy gate electrode 72 over the dummy gate dielectric 71. The dummy gate dielectric 71 may be, for example, silicon oxide, silicon nitride, a combination thereof, or the like, and may be deposited or thermally grown according to acceptable techniques. The dummy gate electrode 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate electrode 72 and the dummy gate dielectric 71 may be formed by, for example, depositing a dummy dielectric layer and a dummy gate layer over the substrate, forming the patterned masks 75 over the dummy gate layer, and then performing a patterning process to the dummy dielectric layer and the dummy gate layer by using the patterned masks 75 as an etching mask. In some embodiments, the dummy gate electrode 72 may be deposited by physical vapor deposition (PVD), CVD, sputter deposition, or other techniques for depositing the selected material. In some embodiments, the dummy gate dielectric 71 may be formed by thermal oxidation.

In some embodiments, the each of the patterned masks 75 includes a first hard mask 76 and a second hard mask 77 over the first hard mask 76. The first hard mask 76 and the second hard mask 77 may be made of different materials. In some embodiments, the first hard mask 76 may be formed of silicon nitride, and the second hard mask 77 may be formed of silicon oxide.

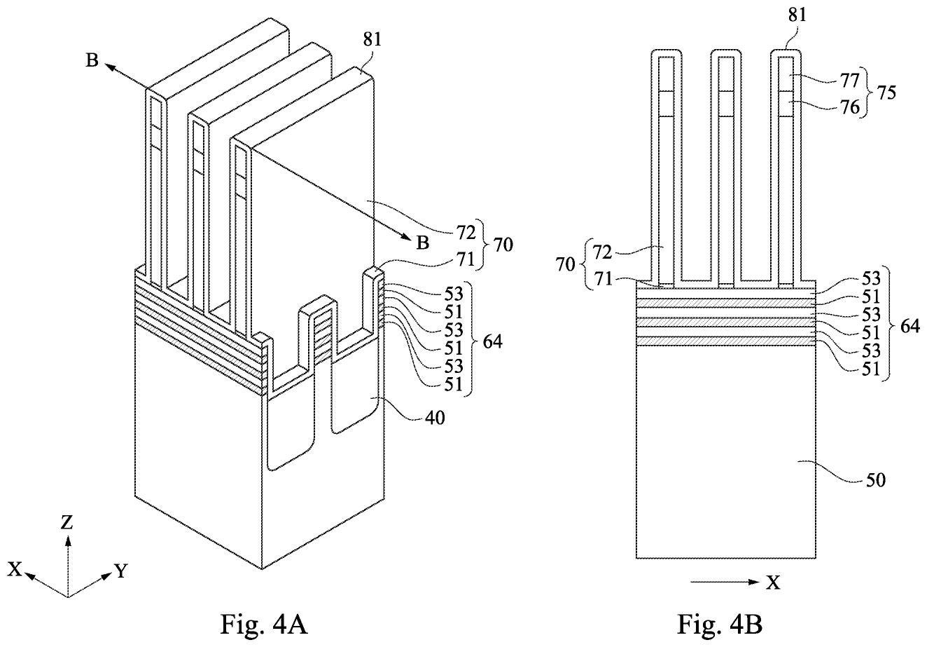

Reference is made to FIGS. 4A and 4B, in which FIG. 4B is a cross-sectional view along line B-B of FIG. 4A. Spacer layer 81 is formed blanketing over the substrate 50. In some embodiments, the spacer layer 81 may extend along surfaces of the patterned masks 75, the dummy gate structures 70, and the stack 64 of the first semiconductor layers 51 and second semiconductor layers 53. The spacer layer 81 may be formed of silicon oxide, silicon nitride, silicon oxynitride, combinations thereof, using techniques such as thermal oxidation or deposited by CVD, ALD, or the like.

Reference is made to FIGS. 5A and 5B. An anisotropic etching process is performed to remove horizontal portions of the spacer layer 81 (see FIGS. 4A and 4B), such that vertical portions of the spacer layer 81 remain on sidewalls of the dummy gate structures 70 and on sidewalls of a portion of the stack 64 on opposite sides of the dummy gate structures 70. The remaining portions of the spacer layer 81 remain on sidewalls of the dummy gate structures 70 can be referred to as gate spacers 82. The remaining portions of the spacer layer 81 remain on sidewalls of the portion of the stack 64 can be referred to as fin spacers 83.

After the gate spacers 82 and the fin spacers 83 are formed, portions of the stack 64 of the first semiconductor layers 51 and second semiconductor layers 53 may be exposed. Then, another etching process may be performed to remove portions of the stack 64 of the first semiconductor layers 51 and second semiconductor layers 53 that are uncovered by the dummy gate structures 70, the gate spacers 82 and the fin spacers 83, so as to form recesses R1. In some embodiments, the bottommost ends of the recesses R1 may be higher than top surfaces of the isolation structures 40 (see FIG. 5A)

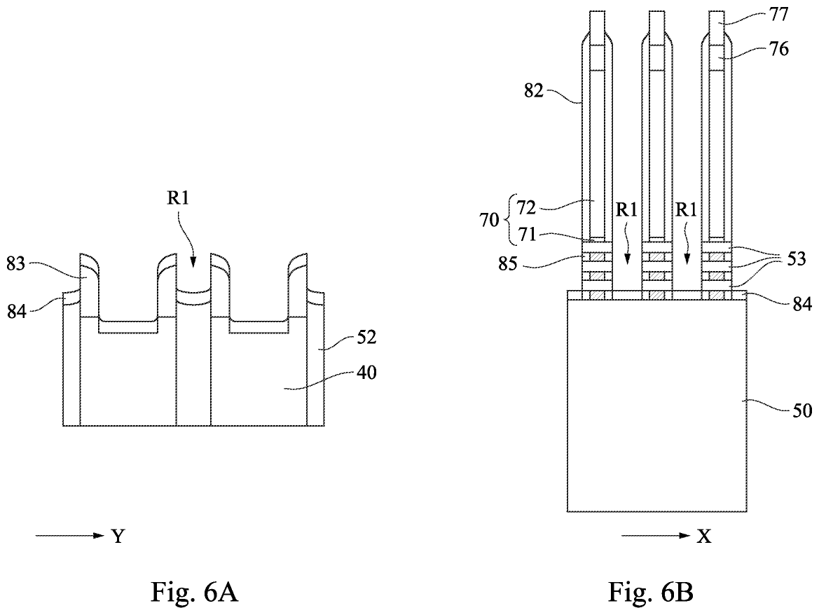

Reference is made to FIGS. 6A and 6B. Portions of the first semiconductor layers 51 exposed by the recesses R1 are laterally etched to form sidewall recesses, and then inner spacers 85 are formed in the sidewall recesses. In some embodiments, the sidewalls of the first semiconductor layers 51 may be etched using isotropic etching processes, such as wet etching or the like. In some embodiments in which the first semiconductor layers 51 include, e.g., SiGe, and the second semiconductor layers 53 include, e.g., Si, a dry etch process with tetramethylammonium hydroxide (TMAH), ammonium hydroxide (NH₄OH), or the like may be used to etch sidewalls of the first semiconductor layers 51.

The inner spacers 85 may be formed by depositing a spacer layer 84 by a conformal deposition process, such as CVD, ALD, or the like. The spacer layer 84 may include a material such as silicon nitride or silicon oxynitride, although any suitable material, such as low-dielectric constant (low-k) materials having a k-value less than about 3.5, may be utilized. In particular, the inner spacers 85 may be formed by depositing the spacer layer 84 blanket over the substrate 50 and filling the sidewall recesses of the first semiconductor layers 51, on the fin spacers 83, on the isolation structures 40 and on the semiconductor strip 52 exposed by the recess R1, and then performing an anisotropic etching to remove unwanted portions of the spacer layer 84. Although outer sidewalls of the inner spacers 85 are illustrated as being flush with sidewalls of the second semiconductor layers 53, the outer sidewalls of the inner spacers 85 may extend beyond or be recessed from sidewalls of the second semiconductor layers 53.

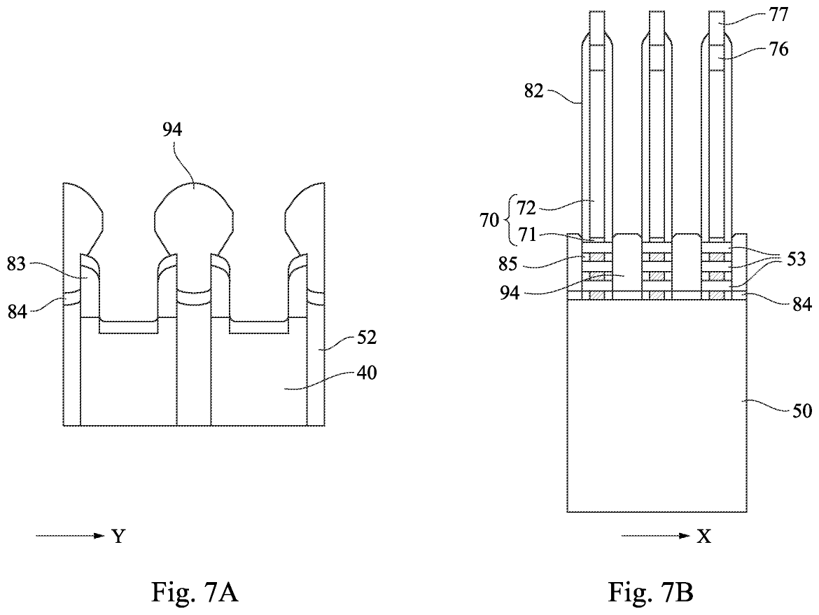

Reference is made to FIGS. 7A and 7B. Epitaxial source/drain structures 94 are formed in the recesses R1. In greater details, the epitaxial source/drain structures 94 may be formed by, for example, performing a deposition process, such as an epitaxial growth, to grow an epitaxial material in the recesses R1 until the epitaxial material filling the recesses R1. In some embodiments, the epitaxial source/drain structures 94 are made of a semiconductor material, and can also be referred to as semiconductor layers. In some embodiments, the epitaxial source/drain structures 94 may include a different composition or different material than the substrate 50. For example, the substrate 50 may be made of Si and the epitaxial source/drain structures 94 may be made of silicon germanium (SiGe). In some other embodiments, the epitaxial source/drain structures 94 may be made of SiGeB.

As illustrated in FIG. 7B, the epitaxial source/drain structures 94 are formed in the recesses R1 such that each dummy gate structure 70 is disposed between respective neighboring pairs of the epitaxial source/drain structures 94. In some embodiments, the gate spacers 82 are used to separate the epitaxial source/drain structures 94 from the dummy gate structures 70, and the inner spacers 85 are used to separate the epitaxial source/drain structures 94 from the first semiconductor layers 51 by an appropriate lateral distance so that the epitaxial source/drain structures 94 do not short out with subsequently formed gates of the resulting nano-FETs. In some embodiments, the epitaxial source/drain structures 94 include n-type epitaxial material such as SiAs, SiP. In other embodiments, the epitaxial source/drain structures 94 include p-type epitaxial material such as SiGe, SiGeB. Source/drain region(s) may refer to a source or a drain, individually or collectively dependent upon the context.

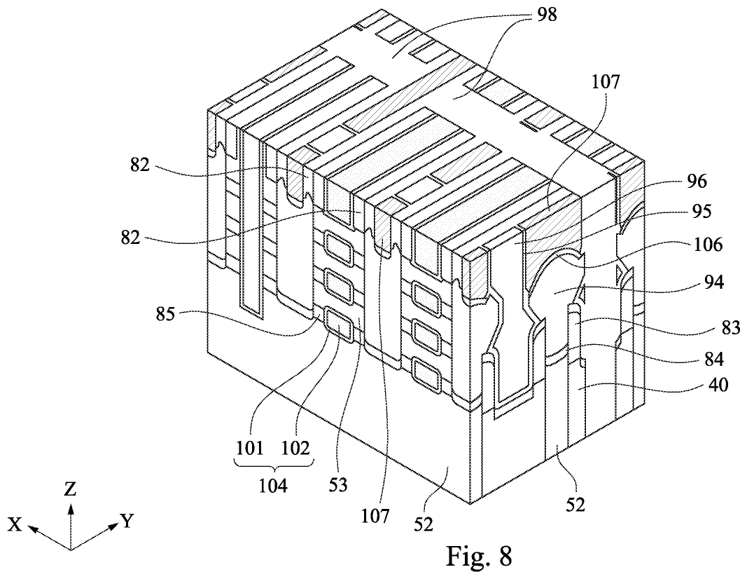

Reference is made to FIG. 8. A first interlayer dielectric (ILD) layer 96 is deposited over the epitaxial source/drain structures 94 and laterally surrounding the dummy gate structures 70. In some embodiments, a CMP process may be performed to the first ILD layer 96 until the top surfaces of the dummy gate structures 70 are exposed. The first ILD layer 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 95 is disposed between the first ILD layer 96 and the epitaxial source/drain structures 94. The CESL 95 may include a dielectric material, such as, silicon nitride, silicon oxide, silicon oxynitride, or the like, having a different etch rate than the material of the overlying first ILD layer 96.

After the first ILD layer 96 and the CESL 95 are formed, gate isolation regions 98 are formed to separate the long dummy gate structures 70. The gate isolation regions 98 are referred to as cut-poly (CPO) regions. In some embodiments, the formation of the gate isolation regions 98 includes forming an etching mask such as a patterned photo resist in which regions where the gate isolation regions 98 are to be formed are revealed through the openings in the etching mask. The portions of the dummy gate structures 70 revealed through the etching mask are then etched. Next, the etching mask is removed, and a dielectric material is deposited to fill the openings in the dummy gate structures 70.

The dummy gate structures 70 are removed to form gate trench between the gate spacers 82. In some embodiments, the dummy gate structures 70 may be removed by an anisotropic dry etch process. For example, the etching process may include a dry etch process using reaction gas(es) that selectively etch the dummy gate structures 70 at a faster rate than the first ILD layer 96 or the gate spacers 82.

Next, the first semiconductor layers 51 are removed through the gate trench, such that portions of the second semiconductor layers 53 are suspended over the substrate 50. The first semiconductor layers 51 may be removed by performing an isotropic etching process such as wet etching or the like using etchants which are selective to the materials of the first semiconductor layers 51, while the second semiconductor layers 53 remain relatively unetched as compared to the first semiconductor layers 51. In embodiments where the first semiconductor layers 51 include, e.g., SiGe, and the second semiconductor layers 53 include, e.g., Si, tetramethylammonium hydroxide (TMAH), ammonium hydroxide (NH₄OH), or the like may be used to remove the first semiconductor layers 51.

After the removal of the first semiconductor layers 51, gate dielectric layers 101 and gate electrodes 102 are formed for replacement gates. The gate dielectric layers 101 are deposited conformally in the gate trenches. The gate dielectric layers 101 may be formed on top surfaces of the semiconductor strips 52 and on top surfaces, sidewalls, and bottom surfaces of the second semiconductor layers 53.

In accordance with some embodiments, the gate dielectric layers 101 may include one or more dielectric layers, such as an oxide, a metal oxide, the like, or combinations thereof. For example, in some embodiments, the gate dielectric layers 101 may include a silicon oxide layer and a metal oxide layer over the silicon oxide layer. In some embodiments, the gate dielectric layers 101 include a high-k dielectric material, and in these embodiments, the gate dielectric layers 101 may have a k value greater than about 7.0, and may include a metal oxide or a silicate of hafnium, aluminum, zirconium, lanthanum, manganese, barium, titanium, lead, and combinations thereof. The formation methods of the gate dielectric layers 101 may include molecular-beam deposition (MBD), ALD, PECVD, and the like.

The gate electrodes 102 are deposited over the gate dielectric layers 101, respectively, and fill the remaining portions of the gate trench. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated, the gate electrodes 102 may include any number of liner layers, any number of work function tuning layers, and a fill material.

After the filling of the gate trenches, a planarization process, such as a CMP, may be performed to remove the excess portions of the gate dielectric layers 101 and the material of the gate electrodes 102, which excess portions are over the top surface of the first ILD layer 96. The remaining portions of material of the gate electrodes 102 and the gate dielectric layers 101 thus form replacement gate structures of the resulting nano-FETs. The gate electrodes 102 and the gate dielectric layers 101 may be collectively referred to as metal gate structures 104.

The first ILD layer 96 is then etched by using, for example, one or more etching processes to form recesses that expose the epitaxial source/drain structures 94. In some embodiments, the one or more etching processes are selective etching that etches the first ILD layer at a faster etch rate than etching the CESL 95.

Subsequently, metal alloy layers 106 are respectively formed above the epitaxial source/drain structures 94. The metal alloy layers 106, which may be silicide layers, are respectively formed over the exposed epitaxial source/drain structures 94 by a self-aligned silicide (salicide) process. The silicide process converts the surface portions of the epitaxial source/drain structures 94 into the silicide contacts. Silicide processing involves deposition of a metal that undergoes a silicidation reaction with silicon (Si). In order to form silicide contacts on the epitaxial source/drain structures 94, a metal material is blanket deposited on the epitaxial source/drain structures 94. After heating the wafer to a temperature at which the metal reacts with the silicon of the epitaxial source/drain structures 94 to form the metal alloy layers 106, unreacted metal is removed. The silicide layers remain over the epitaxial source/drain structures 94, while unreacted metal is removed from other areas. The silicide layer may include a material selected from titanium silicide, cobalt silicide, nickel silicide, platinum silicide, nickel platinum silicide, erbium silicide, palladium silicide, combinations thereof, or other suitable materials. In some embodiments, the metal alloy layers 106 may include germanium.

Source/drain contacts 107 are formed in the first ILD layers 96. In some embodiments, the source/drain contacts 107 may be formed by, for example, etching the first ILD layers 96 to form contact openings, depositing one or more conductive materials in the contact openings, and performing a CMP process to remove excess conductive materials until the top surface of the first ILD layer 96 is exposed. The source/drain contacts 107 may include one or more layers, such as barrier layers, diffusion layers, and fill materials. In some embodiments, the source/drain contacts 107 each may include a barrier layer made of titanium, titanium nitride, tantalum, tantalum nitride, or the like, and a conductive material made of copper, a copper alloy, silver, gold, tungsten, cobalt, aluminum, nickel, or the like.

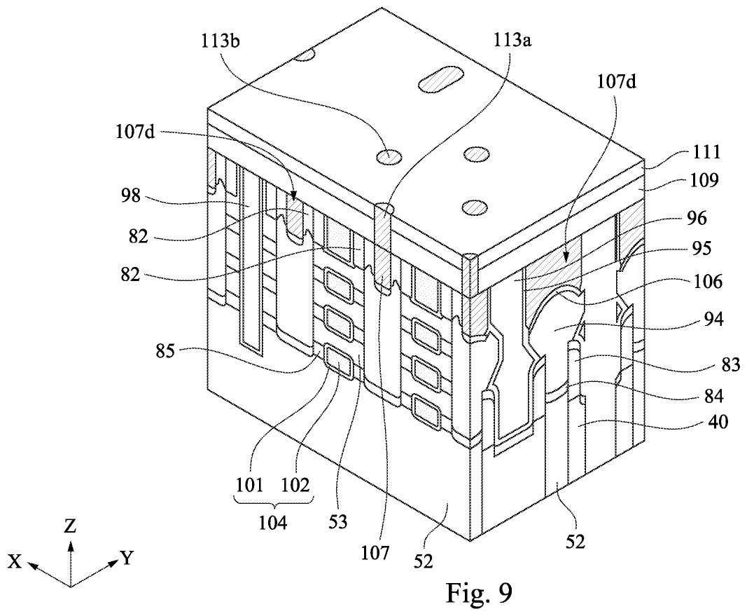

Reference is made to FIG. 9. An etch stop layer 109 and a second interlayer dielectric (ILD) layer 111 are subsequently formed over the structure of FIG. 8. In some examples, the etch stop layer 109 includes a silicon nitride layer, silicon oxide layer, a silicon oxynitride layer, and/or other suitable materials having a different etch selectivity than the second ILD layer 111. The etch stop layer 109 may be formed by plasma-enhanced chemical vapor deposition (PECVD) process and/or other suitable deposition or oxidation processes. In some embodiments, the second ILD layer 111 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the etch stop layer 109. The second ILD layer 111 may be deposited by a PECVD process or other suitable deposition technique. In some embodiments, after formation of the second ILD layer 111, the wafer may be subject to a high thermal budget process to anneal the second ILD layer 111.

Subsequently, a plurality of openings are formed in the etch stop layer 109 and the second ILD layer 111, and at least portions of the epitaxial source/drain structures 94 and at least portions of the metal gate structures 104 are exposed by the openings. The etch stop layer 109 and the second ILD layer 111 may be patterned using a selective etching process (e.g., selective dry etching, selective wet etching, or a combination thereof) that etches materials in the second ILD layer 111 and the etch stop layer 109 at a faster etch rate than it etches the source/drain contacts 107. A conductive material is then formed over the second ILD layer 111, filling into the openings, and a CMP process is then performed to remove the conductive material outside the openings, leaving portions of the conductive material in the openings to serve as conductive vias 113a and conductive vias 113b. The conductive vias 113a are over the epitaxial source/drain structures 94. The conductive vias 113b are over the metal gate structures 104 and can be referred to as gate contacts. The conductive vias 113a, 113b are functional contacts. A first portion of the source/drain contacts 107 are covered by the etch stop layer 109 and the second ILD layer 111. For example, the first portion of the source/drain contacts 107 covered by the etch stop layer 109 and the second ILD layer 111 is not configured to provide function of wiring. Therefore, the first portion of the source/drain contacts 107 is referred to as dummy source/drain contacts 107d.

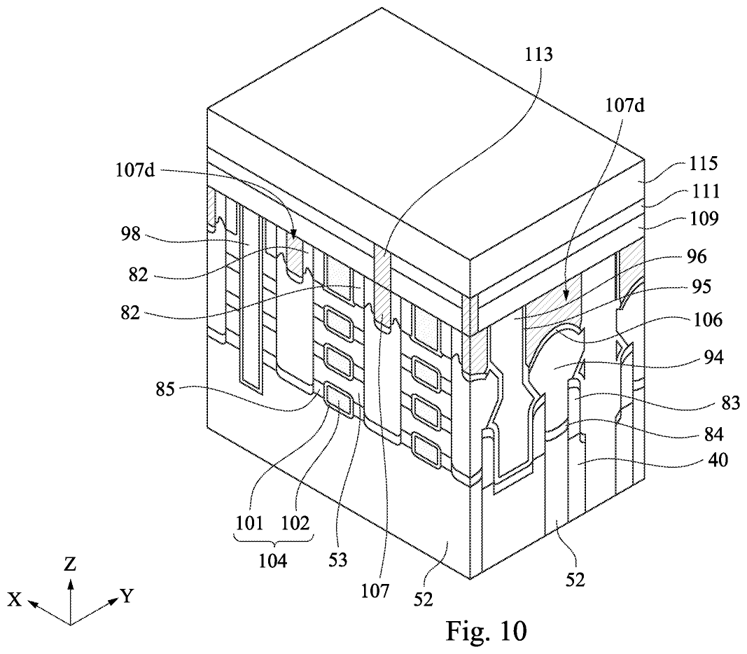

Reference is made to FIG. 10. A hard mask layer 115 is deposited on the second ILD layer 111 and the conductive vias 113. The hard mask layer 115 may include silicon nitride, an oxide material, or the like, and may be formed using a process such as CVD, ALD, or the like.

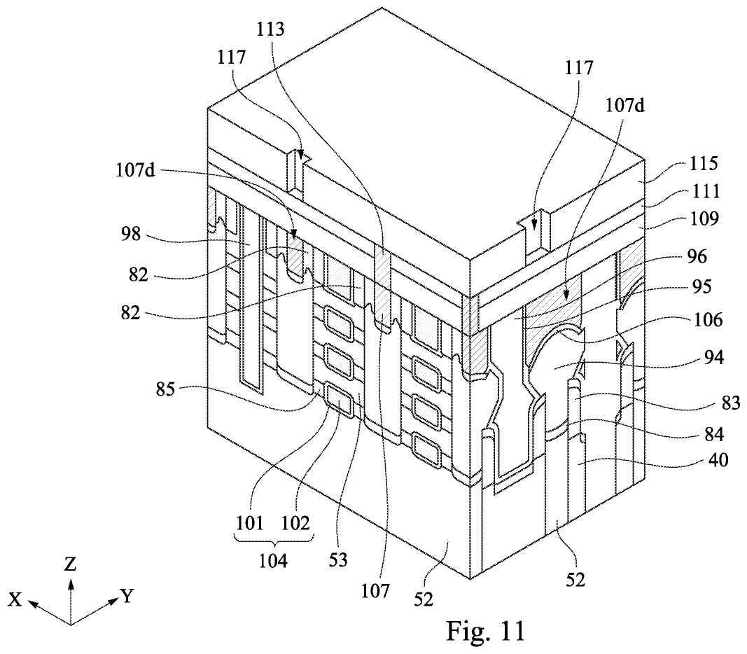

Reference is made to FIG. 11. Subsequently, via patterns 117 are formed in the hard mask layer 115. In some embodiments, the via patterns 117 are formed directly over the dummy source/drain contacts 107d. In other words, the via patterns 117 overlap the dummy source/drain contacts 107d. In some embodiments, the via patterns 117 are formed by patterning the hard mask layer 115 using one or more lithography processes, exposing the second ILD layer 111 over the dummy source/drain contacts 107d.

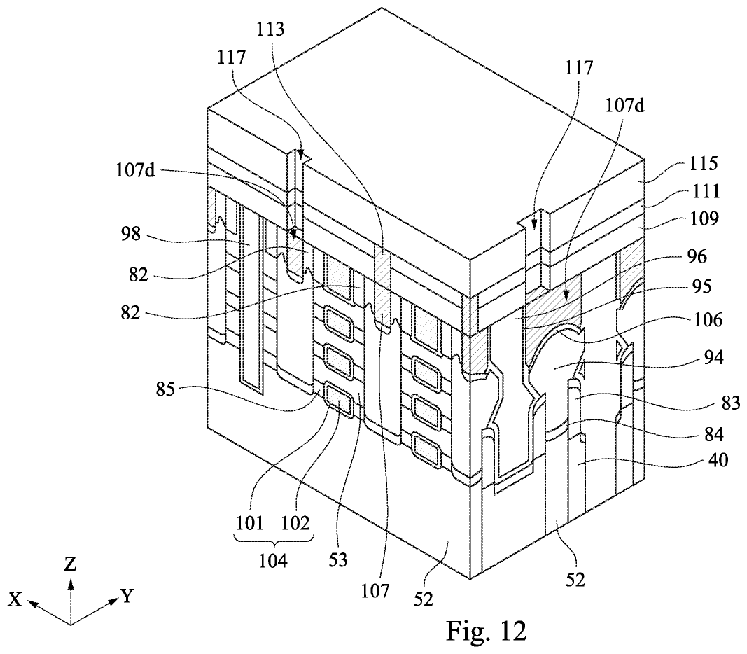

Reference is made to FIG. 12. The second ILD layer 111 and the etch stop layer 109 exposed by the via patterns 117 are etched, exposing the dummy source/drain contacts 107d. For example, the second ILD layer 111 and the etch stop layer 109 are etched using the hard mask layer 115 as an etch mask such as using a dry etch.

Reference is made to FIGS. 13A and 13B. FIG. 13B is a cross-sectional view cutting along Y direction in FIG. 13A in accordance with some embodiments. Reference is made to FIGS. 13A and 13B. The dummy source/drain contacts 107d exposed by the via patterns 117 are etched using the hard mask layer 115, the ILD layer 111 and the etch stop layer 109 as an etch mask, forming spaces 119 over the epitaxial source/drain structures 94. The dummy source/drain contacts 107d may be etched using a selective etching process (e.g., selective dry etching, selective wet etching, or a combination thereof) that etches the dummy source/drain contacts 107d (see FIG. 12) at a faster etch rate than it etches dielectric materials (e.g., the hard mask layer 115, the second ILD layer 111 and the etch stop layer 109). In some other embodiments, a part of the dummy source/drain contacts 107d is remained after being etched (see FIG. 13C). For example, the dummy source/drain contacts 107d have a first portion F1 in the spaces 119. The first portion F1 has a material of same as the material of the dummy source/drain contacts 107d. In some embodiments, the first portion F1 may include one or more layers, such as barrier layers, diffusion layers, and fill materials. In some embodiments, the first portion F1 may include a barrier layer made of titanium, titanium nitride, tantalum, tantalum nitride, or the like, and a conductive material made of copper, a copper alloy, silver, gold, tungsten, cobalt, aluminum, nickel, or the like. Although the first portion F1 is illustrated as having a flat top surface, the present disclosure is not limited thereto. For example, the first portion F1 may have a curved top surface, an irregular top surface or a non-uniform top surface. In some other embodiments, the metal alloy layers 106 are partially removed, and thus the metal alloy layer 106-1 on a right hand side has a shape different from a shape of the metal alloy layer 106-2 on the left hand side (see FIG. 13D). In some embodiments, the top surface of the metal alloy layer 106-1 on the right hand side may have a recess R2.

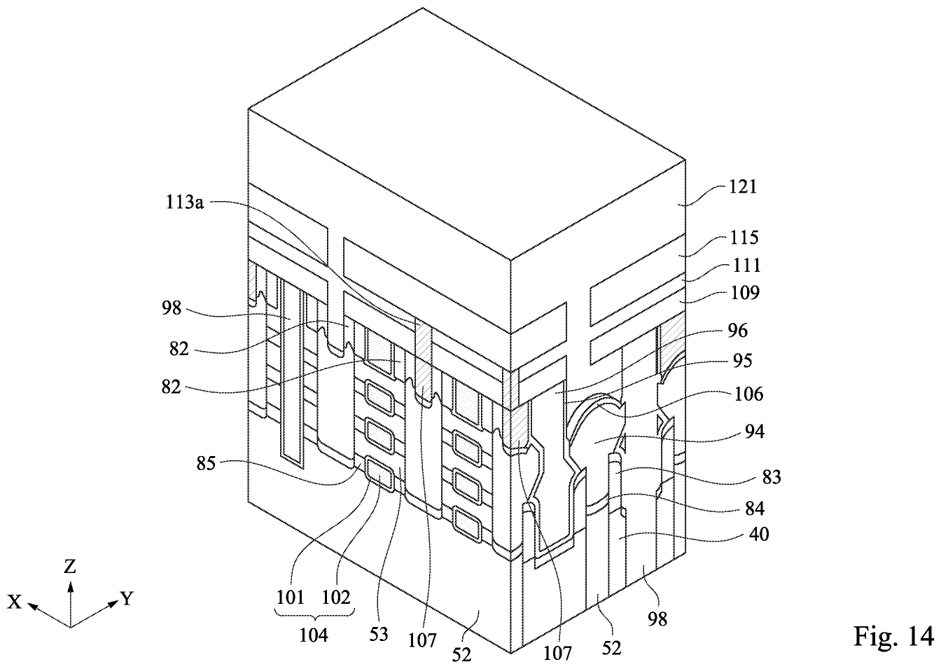

Reference is made to FIG. 14. A dielectric material 121 is formed on the hard mask layer 115, filling into the spaces 119 and the via patterns 117 (see FIG. 13A). That is, the dielectric material 121 is deposited into the spaces 119 and the via patterns 117. The dielectric material 121 may be formed by CVD, ALD, or the like. In some embodiments, the dielectric material 121 includes low-k material such as silicon oxide, silicon nitride, silicon oxynitride, fluoride-doped silicate glass (FSG), or other low-K dielectric materials.

Reference is made to FIGS. 15A-15C. FIG. 15B is a top view of FIG. 15A in accordance with some embodiments. FIG. 15C is a cross-sectional view cutting along Y direction in FIG. 15A in accordance with some embodiments. A CMP process is then performed to remove the dielectric material 121 over the second ILD layer 111, exposing the conductive vias 113. A first portion of the dielectric material 121 embedded in the first ILD layer 96 may be referred to as lower dielectric plug 123. A second portion of the dielectric material 121 embedded in the second ILD layer 111 and in the etch stop layer 109 may be referred to as upper dielectric plugs 125. As discussed previously, the lower dielectric plug 123 and the upper dielectric plugs 125 are not configured to provide function of wiring. Parasitic capacitance between the metal gate structure 104 and the source/drain contacts 107 can be reduced, which improves the device performance of the semiconductor device. The lower dielectric plug 123 and the source/drain contacts 107 are in contact with the silicide regions (i.e., the metal alloy layers 106), respectively.

In FIG. 15B, in some embodiments, via rails 127 are formed on the second ILD layer 111, and the via rails 127 are omitted in FIG. 15A. The metal gate structure 104 has a top surface 104t lower than a top surface 125t of the upper dielectric plug 125 in some embodiments. In some embodiments, the lower dielectric plug 123 is in contact with the metal alloy layers 106. In some embodiments, the lower dielectric plug 123 has a height greater than a height of the upper dielectric plug 125. From a cross-sectional view, the gate spacers 82 are between the lower dielectric plug 123 and the source/drain contact 107. The lower dielectric plug 123 and the source/drain contact 107 may have a same pattern from a plan view (see FIG. 15B). From a plan view, the lower dielectric plug 123 extends along a direction parallel with a longitudinal axis of the metal gate structure 104.

FIG. 15D is a cross-sectional view of some other embodiments of the semiconductor device during fabrication along Y-direction in FIG. 15A. FIG. 15E is a cross-sectional view of some other embodiments of the semiconductor device during fabrication along X-direction in FIG. 15A. Reference is made to FIG. 15D. In some embodiments, during forming the dielectric material 121 on the hard mask layer 115, the dielectric material 121 does not completely fill the via patterns 117 and the spaces 119 such that air gaps 129 may be formed between the epitaxial source/drain structures 94 and the upper dielectric plug 125. The upper dielectric plug 125 and the lower dielectric plug 123 are separated from the epitaxial source/drain structures 94 by the air gaps 129. In other words, the upper dielectric plug 125 is physically separated from the epitaxial source/drain structures 94 by the air gap 129. For example, the upper dielectric plug 125 may have a bottom surface coplanar with the bottom surface of the etch stop layer 109. In some embodiments, the upper dielectric plug 125 has a height 125h substantially the same as a height 113ah of the conductive via 113a.

In FIG. 15E, in some other embodiments, an additional etch stop layer (e.g., an etch stop layer 131) and an additional interlayer dielectric layer (e.g., an interlayer dielectric layer 133) may be formed between the metal gate structure 104 and the etch stop layer 109. Therefore, the source/drain contact 107 has a height 107h higher than a height 104h of the metal gate structure 104. For example, the source/drain contact 107 has a top surface 107t higher than a top surface 104t of the metal gate structure 104. In some cases that the dielectric material 121 does not fill the spaces 119 (see FIG. 13B) entirely, the dielectric material 121 extends below the etch stop layer 109. For example, the dielectric material 121 is laterally between the etch stop layer 109 and the etch stop layer 131. The air gap 129 is present between the etch stop layer 109 and the epitaxial source/drain structures 94. The lower dielectric plug 125 may have a bottom surface defining a boundary of a void region (e.g., the air gap 129). The lower dielectric plug 123 may have a bottom surface (e.g., a bottom surface 123b1 or a bottom surface 123b2) higher than a bottom surface 107b of the source/drain contact 107. In some embodiments, the lower dielectric plug 123 may have the bottom surface 123b1 lower than the top surface 104t of the metal gate structure 104 and the bottom surface 123b2 higher than the top surface 104t of the metal gate structure 104. In some embodiments, the lower dielectric plug 123 has a width decreasing in a direction toward the epitaxial source/drain structure 94. In other words, the lower dielectric plug 123 has a top portion and a bottom portion wider than the top portion.

FIG. 15F is a cross-sectional view of some embodiments of the semiconductor device during fabrication along X-direction in FIG. 15A. FIG. 15G is a cross-sectional view of some embodiments of the semiconductor device during fabrication along Y-direction in FIG. 15A. Reference is made to FIGS. 15F and 15G. In some embodiments, the upper dielectric plug 125 has a width w1 in a range from about 8 nm to about 15 nm in the X-direction and a width w2 in a range from about 8 nm to about 15 nm in the X-direction.

In some embodiments, the source/drain contact 107 has a height h1 in a range from about 8 nm to about 30 nm in the X direction. In some embodiments, the source/drain contact 107 may have the height h1 greater than or equal to a height H1 of the metal gate structure 104. In some embodiments, the dielectric source/drain contact 123 has a width w3 in a range from about 9 nm to about 20 nm in the X direction. In some embodiments, the dielectric source/drain contact 123 has a width w4 in a range from about 12 nm to about 100 nm in the Y direction. In some embodiments, the second ILD layer 111 has a height h2 in a range from about 2 nm to about 15 nm. In some embodiments, the etch stop layer 109 has a height h3 in a range from about 2 nm to about 15 nm.

Reference is made to FIGS. 16A and 16B. The structure in FIGS. 16A and 16B is similar to the structure in FIGS. 15B and 15F, except for the upper dielectric plugs 125a on adjacent dielectric source/drain contacts 123 being in contact with each other. In particular, an additional etch stop layer (e.g., the etch stop layer 131) and an additional interlayer dielectric layer (e.g., the interlayer dielectric layer 133) may be formed between the metal gate structure 104 and the etch stop layer 109. Therefore, the source/drain contact 107 has the height higher than the height of the metal gate structure 104. Due to the source/drain contact 107 having the height higher than the height of the metal gate structure 104, the upper dielectric plugs 125a may be formed as a slot shape in the X-direction. That is, the upper dielectric plugs 125a extend across the gate isolation regions 98 along the X-direction. In other words, the upper dielectric plugs 125a on adjacent dielectric source/drain contacts 123 are in contact with each other.

Reference is made to FIGS. 17A and 17B. The structure in FIGS. 17A and 17B is similar to the structure in FIGS. 15B and 15F, except for the upper dielectric plugs 125b on adjacent dielectric source/drain contacts 123 being in contact with each other. In particular, an additional etch stop layer (e.g., the etch stop layer 131) and an additional interlayer dielectric layer (e.g., the interlayer dielectric layer 133) may be formed between the metal gate structure 104 and the etch stop layer 109. Therefore, the source/drain contact 107 has the height higher than the height of the metal gate structure 104. Due to the source/drain contact 107 having the height than the height of the metal gate structure 104, the upper dielectric plugs 125b may be formed as a slot shape in the Y-direction. That is, the upper dielectric plugs 125b extend across the gate isolation regions 98 along the Y-direction. In other words, the upper dielectric plugs 125b on adjacent dielectric source/drain contacts 123 are in contact with each other.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that by replacing the dummy source/drain contact with the lower dielectric plug and the upper dielectric plug, the parasitic capacitance between the metal gate structure and the source/drain contact can be reduced. Another advantage is that due to the reduced parasitic capacitance, the device performance of the semiconductor device can be improved.

In some embodiments, a semiconductor device comprises semiconductor layers extending over a substrate, a gate structure, gate spacers, epitaxial source/drain structures, a conductive contact and a lower dielectric plug. The gate structure wraps around the semiconductor layers. The gate spacers are on opposite sidewalls of the gate structure. The epitaxial source/drain structures are on opposite sides of the metal gate structure. The conductive contact is over a first one of the epitaxial source/drain structures. The lower dielectric plug is over a second one of epitaxial source/drain structures, wherein from a cross-sectional view, the gate spacers are between the lower dielectric plug and the conductive contact, wherein from a plan view, the lower dielectric plug and the conductive contact have a same pattern. In some embodiments, the semiconductor device further comprises a conductive via on the conductive contact and an upper dielectric plug on the lower dielectric plug. In some embodiments, the gate structure has a top surface lower than a top surface of the upper dielectric plug. In some embodiments, the lower dielectric plug is separated from the second one of epitaxial source/drain structures by an air gap. In some embodiments, the lower dielectric plug has a bottom surface higher than a bottom surface of the conductive contact. In some embodiments, a bottom surface of the lower dielectric plug has a first portion lower than a top surface of the gate structure and a second portion higher than the top surface of the metal gate structure. In some embodiments, the lower dielectric plug has a width decreasing in a direction toward the second one of the epitaxial source/drain structures. In some embodiments, the lower dielectric plug has a bottom surface defining a boundary of a void region. In some embodiments, the semiconductor device further comprises a silicide layer between the lower dielectric plug and the second one of the epitaxial source/drain structures. In some embodiments, the lower dielectric plug is in contact with the silicide layer.

In some embodiments, a method of forming a semiconductor device comprises the following steps. A fin structure is formed over a substrate. Epitaxial source/drain structures are formed on the fin structure. A gate structure is formed between the epitaxial source/drain structures. An interlayer dielectric (ILD) layer is formed over the epitaxial source/drain structures. The ILD layer is etched to form openings exposing the epitaxial source/drain structures. A dielectric material is formed in a first one of the openings and a conductive material in a second one of the openings. In some embodiments, the dielectric material has a top surface higher than a top surface of the gate structure. In some embodiments, from a plan view, the dielectric material extends along a direction parallel with a longitudinal axis of the gate structure. In some embodiments, the method further comprises prior to forming the dielectric material in the first one of the openings and the conductive material in the second one of the openings, forming silicide regions on the epitaxial source/drain structures. In some embodiments, the dielectric material and the conductive material are in contact with the silicide regions, respectively.

In some embodiments, a method of forming a semiconductor device comprises the following steps. A fin is formed protruding from a substrate. Epitaxial source/drain structures are formed on the fin. A first interlayer dielectric (ILD) layer is deposited over the epitaxial source/drain structures. The first ILD layer is patterned to form first openings exposing the epitaxial source/drain structures. The first openings are filled with a conductive material to form a functional contact and a dummy contact respectively over the epitaxial source/drain structures. A second ILD layer is formed over the first ILD layer, the functional contact and the dummy contact. The second ILD layer and the dummy contact are etched to form a second opening. A dielectric material is deposited into the second opening. In some embodiments, the dielectric material has a top portion and a bottom portion wider than the top portion. In some embodiments, the dielectric material has a top portion embedded in the second ILD layer and a bottom portion embedded in the first ILD layer, and the bottom portion has a height greater than a height of the top portion. In some embodiments, the dielectric material is separated from the epitaxial source/drain structures by an air gap. In some embodiments, the method further comprises prior to etching the second ILD layer and the dummy contact to form the second opening, forming a conductive via on the functional contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
semiconductor layers extending over a substrate;
a gate structure wrapping around the semiconductor layers;
gate spacers on opposite sidewalls of the gate structure;
epitaxial source/drain structures on opposite sides of the gate structure;
a conductive contact over a first one of the epitaxial source/drain structures; and
a lower dielectric plug over a second one of epitaxial source/drain structures, wherein from a cross-sectional view, the gate spacers are between the lower dielectric plug and the conductive contact, wherein from a plan view, the lower dielectric plug and the conductive contact have a same pattern.

2. The semiconductor device of claim 1, further comprising:
a conductive via on the conductive contact; and
an upper dielectric plug on the lower dielectric plug.

3. The semiconductor device of claim 2, wherein the gate structure has a top surface lower than a top surface of the upper dielectric plug.

4. The semiconductor device of claim 1, wherein the lower dielectric plug is separated from the second one of epitaxial source/drain structures by an air gap.

5. The semiconductor device of claim 1, wherein the lower dielectric plug has a bottom surface higher than a bottom surface of the conductive contact.

6. The semiconductor device of claim 1, wherein a bottom surface of the lower dielectric plug has a first portion lower than a top surface of the gate structure and a second portion higher than the top surface of the gate structure.

7. The semiconductor device of claim 1, wherein the lower dielectric plug has a width decreasing in a direction toward the second one of the epitaxial source/drain structures.

8. The semiconductor device of claim 1, wherein the lower dielectric plug has a bottom surface defining a boundary of a void region.

9. The semiconductor device of claim 1, further comprising:
a silicide layer between the lower dielectric plug and the second one of the epitaxial source/drain structures.

10. The semiconductor device of claim 9, wherein the lower dielectric plug is in contact with the silicide layer.

11. A method of forming a semiconductor device, comprising:
forming a fin structure over a substrate;
forming epitaxial source/drain structures on the fin structure;
forming a gate structure between the epitaxial source/drain structures;
forming an interlayer dielectric (ILD) layer over the epitaxial source/drain structures;
etching the ILD layer to form openings exposing the epitaxial source/drain structures; and
forming a dielectric material in a first one of the openings and a conductive material in a second one of the openings.

12. The method of claim 11, wherein the dielectric material has a top surface higher than a top surface of the gate structure.

13. The method of claim 11, wherein from a plan view, the dielectric material extends along a direction parallel with a longitudinal axis of the gate structure.

14. The method of claim 11, further comprising:
prior to forming the dielectric material in the first one of the openings and the conductive material in the second one of the openings, forming silicide regions on the epitaxial source/drain structures.

15. The method of claim 14, wherein the dielectric material and the conductive material are in contact with the silicide regions, respectively.

16. A method of forming a semiconductor device, comprising:
forming a fin protruding from a substrate;
forming epitaxial source/drain structures on the fin;
depositing a first interlayer dielectric (ILD) layer over the epitaxial source/drain structures;
patterning the first ILD layer to form first openings exposing the epitaxial source/drain structures;
filling the first openings with a conductive material to form a functional contact and a dummy contact respectively over the epitaxial source/drain structures;
forming a second ILD layer over the first ILD layer, the functional contact and the dummy contact;
etching the second ILD layer and the dummy contact to form a second opening; and
depositing a dielectric material into the second opening.

17. The method of claim 16, wherein the dielectric material has a top portion and a bottom portion wider than the top portion.

18. The method of claim 16, wherein the dielectric material has a top portion embedded in the second ILD layer and a bottom portion embedded in the first ILD layer, and the bottom portion has a height greater than a height of the top portion.

19. The method of claim 16, wherein the dielectric material is separated from the epitaxial source/drain structures by an air gap.

20. The method of claim 16, further comprising:
prior to etching the second ILD layer and the dummy contact to form the second opening, forming a conductive via on the functional contact.
